(19) United States
(12) Patent Application Publication
(10) Pub. No.: US 2026/0372180 A1
(43) Pub. Date: Nov. 19, 2026

(54) PACKAGE STRUCTURE HAVING DAM STRUCTURE

(71) Applicant: Taiwan Semiconductor Manufacturing Company, Ltd., Hsinchu (TW)

(72) Inventors: Yi Wen Huang, Hsinchu City (TW); Chih-Hao Chen, Taipei City (TW); Ping-Yin Hsieh, Hsinchu City (TW); Yi-Huan Liao, Hsinchu (TW); Li-Hui Cheng, New Taipei City (TW)

(73) Assignee: Taiwan Semiconductor Manufacturing Company, Ltd., Hsinchu (TW)

(21) Appl. No.: 19/752,645

(22) Filed: Jul. 24, 2026

Related U.S. Application Data
(63) Continuation of application No. 18/446,413, filed on Aug. 8, 2023.

(51) Int. Cl. H10W 76/47; H10B 80/00; H10W 40/22; H10W 90/00

(52) U.S. Cl. CPC H10W 76/47; H10B 80/00; H10W 40/22; H10W 90/00

(57) ABSTRACT

A package structure including a packaging substrate, a semiconductor device, passive components, a lid, and a dam structure is provided. The semiconductor device is disposed on and electrically connected to the packaging substrate. The passive components are disposed on the packaging substrate, wherein the semiconductor device is surrounded by the passive components. The lid is disposed on the packaging substrate, and the lid covers the semiconductor device and the passive components. The dam structure is disposed between the packaging substrate and the lid, wherein the dam structure covers the passive components and laterally encloses the semiconductor device.

### CROSS-REFERENCE TO RELATED APPLICATION

This application is a continuation application of and claims the priority benefit of a prior application Ser. No. 18/446,413, filed on Aug. 8, 2023 and now pending. The entirety of the above-mentioned patent applications is hereby incorporated by reference herein and made a part of this specification.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed, greater bandwidth as well as lower power consumption and latency has grown recently, there has grown a need for large-scaled and reliable electronic apparatus which utilizes advanced packaging techniques of semiconductor dies. For large-scaled electronic apparatus, the reliability issue of packages is a problem to be solved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 are cross-sectional views schematically illustrating a process flow for fabricating a Chip-on-Wafer-on Substrate (CoWoS) structure in accordance with some embodiments of the present disclosure.

FIG. 5 is a top view schematically illustrating the relationship between a dam structure and passive components mounted on a packaging substrate in accordance with some embodiments of the present disclosure.

FIG. 6 is a cross-sectional view schematically illustrating a Chip-on-Wafer-on Substrate (CoWoS) structure in accordance with some alternative embodiments of the present disclosure.

FIGS. 7-10 are cross-sectional views schematically illustrating a process flow for fabricating a Chip-on-Wafer-on Substrate (CoWoS) structure in accordance with some embodiments of the present disclosure.

FIG. 11 is a top view schematically illustrating the relationship between a dam structure and passive components mounted on a packaging substrate in accordance with some alternative embodiments of the present disclosure.

FIG. 12 is a cross-sectional view schematically illustrating a Chip-on-Wafer-on Substrate (CoWoS) structure in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

To improve reliability of CoWoS structures, various novel designed dam structures in the CoWoS structures are provided in accordance with various embodiments. Throughout the various views and illustrative embodiments, like reference numbers are used to designate like elements. It is appreciated that although the CoWoS structure is used as examples to explain the concept of the embodiments of the present disclosure, the embodiments of the present disclosure are readily applicable to other similar dam structure designs.

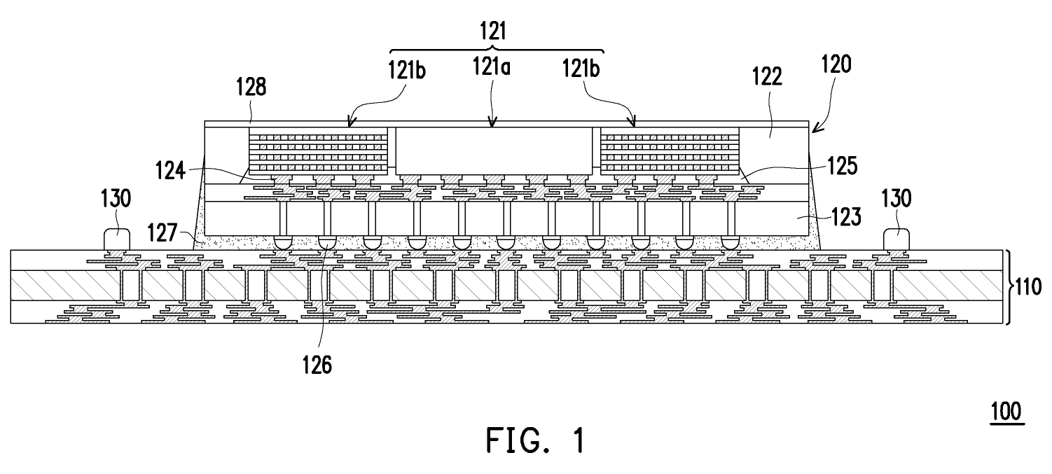

FIGS. 1-4 are cross-sectional views schematically illustrating a process flow for fabricating a CoWoS structure in accordance with some embodiments of the present disclosure.

Referring to FIG. 1, a package structure 100 including a packaging substrate 110, a semiconductor device 120, and passive components 130 is provided. The semiconductor device 120 and the passive components 130 are mounted on the top surface of the packaging substrate 110. The semiconductor device 120 and the passive components 130 are electrically connected to the packaging substrate 110. The semiconductor device 120 may include at least one semiconductor die 121 and an insulating encapsulation 122 laterally encapsulating the at least one semiconductor die 121. The semiconductor device 120 may further includes an interposer wiring substrate 123, conductive terminals 124, a dielectric layer 125, conductive terminals 126, and a dielectric layer 127. For instance, the package structure 100 including the packaging substrate 110, the semiconductor device 120, and passive components 130 is referred as a Chip-on-Wafer-on-Substrate (CoWoS) structure.

As illustrated in FIG. 1, the packaging substrate 110 may be a printed circuit board or other suitable types of wiring substrate. The at least one semiconductor die 121 may be or include at least one first semiconductor die 121a and at least one second semiconductor die 121b. The at least one first semiconductor die 121a and the at least one second semiconductor die 121b are disposed on the interposer wiring substrate 123 in side-by-side manner. In some embodiments, the first semiconductor die 121a includes a High-Bandwidth-Memory (HBM) cube including stacked HBM memory dies and controller die for controlling the operation of the stacked HBM memory dies, and the second semiconductor die 121b includes a System-on-Chip (SoC) die. In some other embodiments, the first semiconductor die 121a and the second semiconductor die 121b may be System on Integrated Circuit (SoIC) dies with various functions. The first semiconductor die 121a and the second semiconductor die 121b are disposed on the interposer wiring substrate 123 and electrically connected to the interposer wiring substrate 123 through the conductive terminals 124. The semiconductor dies 121 are bonded with the interposer wiring substrate 123 through the conductive terminals 124 by a Chip-on-Wafer (CoW) bonding process. The conductive terminals 124 are disposed between the semiconductor dies 121 and the interposer wiring substrate 123. The conductive terminals 124 may be or include micro-bumps for electrically connecting the semiconductor dies 121 and the interposer wiring substrate 123. The dielectric layer 125 is disposed on the interposer wiring substrate 123. The dielectric layer 125 is disposed between the semiconductor dies 121 and the interposer wiring substrate 123 to laterally encapsulate the conductive terminals 124. In some embodiments, the dielectric layer 125 includes underfill material, molding compound, polymer, oxide materials, nitride materials or combinations thereof. Accordingly, shearing stress suffered by the conductive terminals 124 may be minimized by the dielectric layer 125, and the reliability of the conductive terminals 124 may be enhanced by the dielectric layer 125. The material of the dielectric layer 125 may be or include epoxy resin or other suitable dielectric materials.

As illustrated in FIG. 1, the insulating encapsulation 122 is disposed on the interposer wiring substrate 123 to laterally encapsulate the semiconductor dies 121 and the dielectric layer 125. The top surfaces (e.g., the back surfaces) of the semiconductor dies 121 are substantially level with the top surface of the insulating encapsulation 122, and the sidewalls of the insulating encapsulation 122 are substantially aligned with the sidewalls of the interposer wiring substrate 123. The conductive terminals 126 are disposed on the bottom surface of the interposer wiring substrate 123, and the interposer wiring substrate 123 is electrically connected to the packaging substrate 110 through the conductive terminals 126. The conductive terminals 126 may be or include Controlled Collapse Chip Connection bumps (C4 bumps) for electrically connecting the interposer wiring substrate 123 and the packaging substrate 110. The dielectric layer 127 is disposed on the packaging substrate 110. The dielectric layer 127 is disposed between the interposer wiring substrate 123 and the packaging substrate 110 so as to laterally encapsulate the conductive terminals 126. In some embodiments, the dielectric layer 127 includes underfill material, molding compound, polymer, oxide materials, nitride materials or combinations thereof. Furthermore, the dielectric layer 127 covers sidewalls of the interposer wiring substrate 123 as well as lower portions of sidewalls of insulating encapsulation 122.

As illustrated in FIG. 1, the semiconductor dies 121 are electrically connected to the packaging substrate 110 through the interposer wiring substrate 123, the conductive terminals 124 and the conductive terminals 126. The interposer wiring substrate 123 may include a silicon interposer, an organic interposer or other suitable interposer wiring substrate. The interposer wiring substrate 123 may include conductive wirings formed thereon. Furthermore, the interposer wiring substrate 123 may include conductive through vias formed therein. The interposer wiring substrate 123 may be a silicon interposer wiring substrate with fine line pitch (e.g., sub-um pitch), an organic interposer wiring substrate with less aggressive fine line pitch (e.g., 4um pitch) or an interposer wiring substrate with Local Silicon Interconnect (LSI) die. In an embodiment where the interposer wiring substrate 123 is a silicon interposer wiring substrate, the CoWoS package structure 100 is so-called a CoWoS-S package. In an embodiment where the interposer wiring substrate 123 is an organic interposer wiring substrate, the CoWoS package structure 100 is so-called a CoWoS-R package. In an embodiment where the interposer wiring substrate 123 is an interposer wiring substrate with Local Silicon Interconnect (LSI) die, the CoWoS package structure 100 is so-called a CoWoS-L package.

In some embodiments, the semiconductor device 120 may further include a backside metal layer 128 disposed on the top surfaces (e.g., the back surfaces) of the semiconductor dies 121 and the top surface of the insulating encapsulation 122. The backside metal layer 128 covers and is in contact with the top surfaces (e.g., the back surfaces) of the semiconductor dies 121 and the top surface of the insulating encapsulation 122. The backside metal layer 128 may be a single layered metallic structure or a multi-layered metallic structure. The backside metal layer 128 may be or include a copper layer or other metallic layer with favorable thermal conductivity.

The passive components 130 may be surface mounted devices (SMD) mounted on the top surface of the packaging substrate 110. The passive components 130 may be or include capacitors, inductors, resistors, or the like. The passive components 130 are laterally spaced apart from the semiconductor device 120. In other words, the passive components 130 are spaced apart from and are not in contact with the dielectric layer 180 of the insulating encapsulation 122 of the semiconductor device 120.

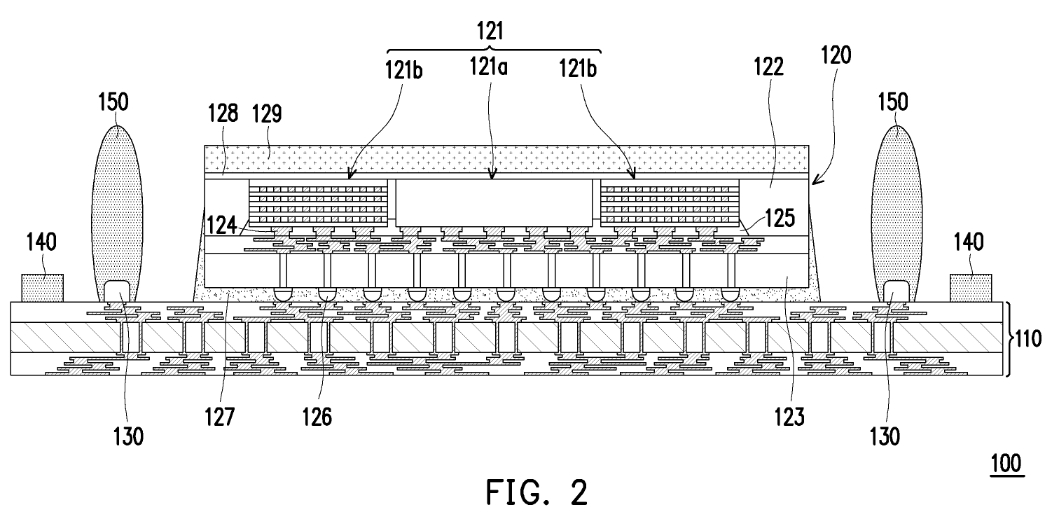

Referring to FIG. 2, an adhesive 140 is applied on the packaging substrate 110. The material of the adhesive 140 may be or include thermally conductive adhesive, silicone based adhesive or epoxy resin-based adhesive. The material of the adhesive 140 may be or include rubber based having curing promoting material. In some embodiments, the adhesive 140 is applied on the top surface of the packaging substrate 110. In addition, the adhesive 140 may include multiple adhesion patterns separated from one another.

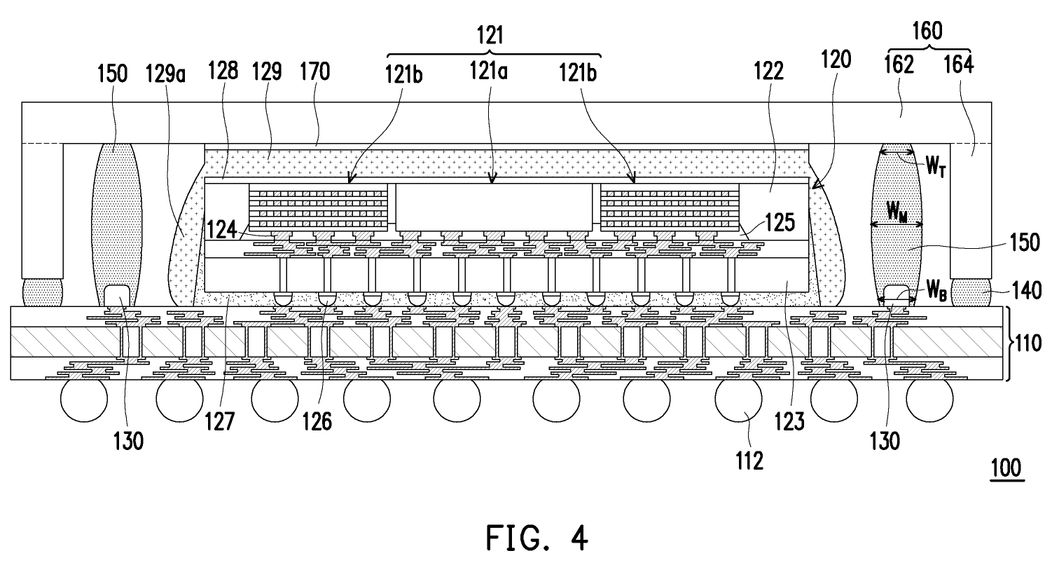

In some embodiments, a thermal interface material (TIM) 129 is applied over the top surfaces (e.g., the back surfaces) of the semiconductor dies 121 and the top surface of the insulating encapsulation 122. For instance, the thermal interface material (TIM) 129 is applied on the top surface of the backside metal layer 128 such that the backside metal layer 128 is disposed between the thermal interface material (TIM) 129 and the semiconductor device 120. The thermal interface material 129 may be or include deformable and/or flowable material during the joint process of a lid 160 (shown in FIG. 4) and the semiconductor die 120. For instance, the thermal interface material 129 is metal thermal interface material (TIM) or the like.

As illustrated in FIG. 2, a dam structure 150 is formed on the top surface of the packaging substrate 110. The dam structure 150 may be wide enough to cover the passive components 130. The passive components 130 may be sealed by the dam structure 150. The dam structure 150 is in contact with the passive components 130. The dam structure 150 may be laterally spaced apart from the semiconductor device 120. In some embodiments, the height of the dam structure 150 substantially levels with the top surface of the thermal interface material (TIM) 129. In some other embodiments, the height of the dam structure 150 is higher than the top surface of the thermal interface material (TIM) 129.

The dam structure 150 may have a bottom width W_{B}, a middle width W_{M}, and a top width W_{T}, wherein the middle width W_{M} of the dam structure 150 is greater than the bottom width W_{B} of the dam structure 150 and the top width W_{T} of the dam structure 150. Furthermore, the bottom width W_{B} of the dam structure 150 may be different from the top width W_{T} of the dam structure 150. In some embodiments, the bottom width W_{B} of the dam structure 150 is greater than the top width W_{T} of the dam structure 150. In some alternative embodiments, the bottom width W_{B} of the dam structure 150 is less than the top width W_{T} of the dam structure 150. In order to cover as well as seal the passive components 130 properly, the bottom width W_{B} of the dam structure 150 may be greater than the lateral dimension of the passive components 130. The passive components 130 may be arranged along a ring-shaped path, and the dam structure 150 may covers as well as extend along the ring-shaped path such that the passive components 130 are covered and the semiconductor device 120 is laterally surrounded by the dam structure 150. Furthermore, the semiconductor device 120 is disposed within a region (e.g., an inner region) surrounded by the dam structure 150, and the adhesive 140 is distributed outside the region (e.g., an outer region) surrounded by the dam structure 150. The inner region surrounded by the dam structure 150 (i.e., the region where the semiconductor device 120 is disposed) is an air-tight region. In other words, the inner region surrounded by the dam structure 150 (i.e., the region where the semiconductor device 120 is disposed) is sealed by the dam structure 150 and is not communicated with the external environment.

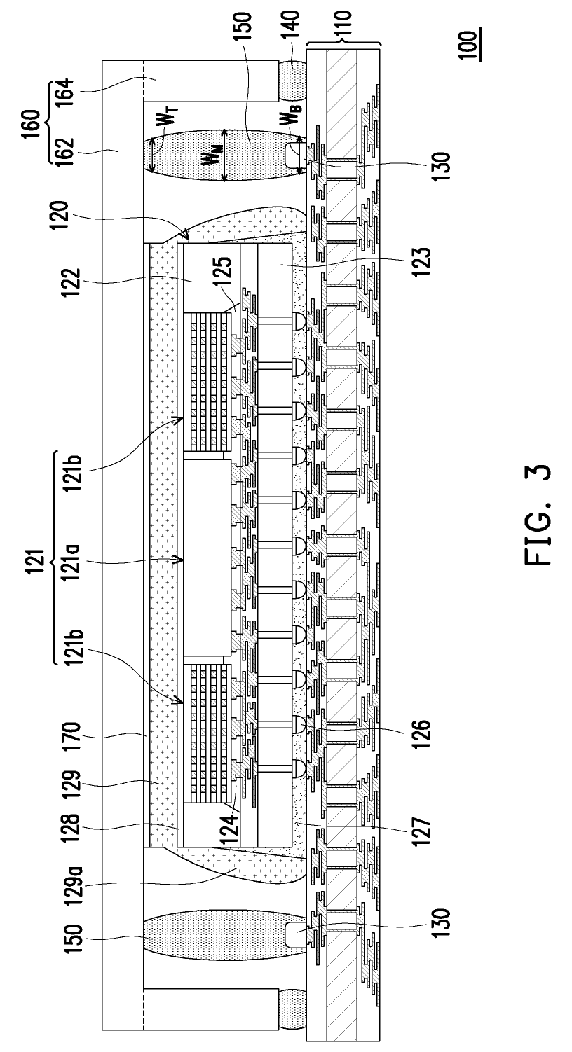

Referring to FIG. 3, after the thermal interface material 129, the adhesive 140, and the dam structure 150 are formed, a lid 160 is provided and attached onto the package structure 100 such that the thermal interface material (TIM) 129 is disposed between the semiconductor device 120 and the lid 160. The lid 160 is attached onto the packaging substrate 110 through the adhesive 140 formed therebetween such that the dam structure 150 is disposed between the packaging substrate 110 and the lid 160. The lid 160 is mounted onto the top surface of the packaging substrate 110 to cover the dam structure 150, the passive components 130 encapsulated by the dam structure 150, and the semiconductor device 120. The lid 160 includes a cover portion 162 and a foot portion 164 extending from the bottom surface of the cover portion 162 to the packaging substrate 110. The cover portion 162 covers the semiconductor dies 121, the insulating encapsulation 122, the thermal interface material 129, and the dam structure 150. The bottom surface of the foot portion 164 of the lid 160 is attached to the packaging substrate 110 through the adhesive 140, and the cover portion 162 of the lid 160 is attached to the semiconductor device 120 through the thermal interface material 129. In some embodiments, a metal layer 170 is applied on the bottom surface of the cover portion 162, and the cover portion 162 of the lid 160 is attached to the semiconductor device 120 through the metal layer 170, the thermal interface material 129 and the backside metal layer 128.

The lid 160 may further include an alignment notch (not shown) formed at a corner of the lid 160 such that the lid 160 may be assembled with the packaging substrate 110 precisely and rapidly.

In some embodiments where the adhesive 140 includes multiple adhesion patterns separated from one another, the foot portion 164 of the lid 160 is adhered with as well as spaced apart from the top surface of the packaging substrate 110 by the multiple adhesion patterns of the adhesive 140. Since the adhesive 140 includes multiple adhesion patterns, a region (e.g., an outer region) between the dam structure 150 and the foot portion 164 of the lid 160 is not an air-tight or sealed region. In other words, the outer region between the dam structure 150 and the foot portion 164 of the lid 160 is communicated with the external environment. As illustrated in FIG. 3, in some embodiments, a cavity is between the packaging substrate 110 and the lid 160, and the cavity includes an inner region between the semiconductor device 120 and the dam structure 150; and an outer region between the dam structure 150 and the foot portion 162 of the lid 160. For instance, the inner region is an air-tight region, the outer region is an open region, and the inner region is spaced apart from the outer region by the dam structure 150.

In some embodiments, the thermal interface material (TIM) 129 includes a metallic thermal interface material, and the metallic thermal interface material covers a top surface and sidewalls of the semiconductor device 120. In some embodiments, the metallic thermal interface material is in contact with the dam structure 150.

As illustrated in FIG. 3, when the lid 160 is provided and pressed onto the package structure 100, the thermal interface material 129 is pressed by the cover portion 162 of the lid 160 such that the thermal interface material 129 deforms and flow outwardly. Deformed portions 129a of the thermal interface material 129 may flow laterally and downwardly to cover sidewalls of the semiconductor device 120. In some embodiments, the deformed portions 129a of the thermal interface material 129 are in contact with the dielectric layer 127. In some other embodiments, the deformed portions 129a of the thermal interface material 129 are in contact with the dielectric layer 127 as well as the dam structure 150. In some embodiments, the region enclosed by the cover portion 162 of the lid 160, the dam structure 150, the packaging substrate 110 and the semiconductor device 120 is filled by the deformed portions of the thermal interface material 129. In some alternative embodiments, the region enclosed by the cover portion 162 of the lid 160, the dam structure 150, the packaging substrate 110 and the semiconductor device 120 is partially filled by the deformed portions of the thermal interface material 129.

As illustrated in FIG. 3, when the lid 160 is provided and pressed onto the package structure 100, the dam structure 150 is pressed by the cover portion 162 of the lid 160 such that the dam structure 150 deformed as well as the top end of the dam structure 150 is adhered with the bottom surface of the cover portion 162 of the lid 160. In some embodiments, the dam structure 150 is laterally spaced apart from the semiconductor device 120, and the deformed portions of the thermal interface material 129 are in contact with the dielectric layer 127 as well as the dam structure 150.

Referring to FIG. 4, conductive terminals 112 are formed on the bottom surface of the packaging substrate 110. The conductive terminals 112 formed on the bottom surface of the packaging substrate 110 may be solder balls arranged in array, and the solder balls may be formed by, for example, a ball mount process followed by a reflowing process. In some embodiments where the conductive terminals 112 include solder balls, the packaging substrate 110 is a ball grid array (BGA) circuit board. After the conductive terminals 112 are formed on the bottom surface of the packaging substrate 110, a singulation process may be performed to cut the packaging substrate 110 to obtain singulated semiconductor devices as shown in FIG. 4.

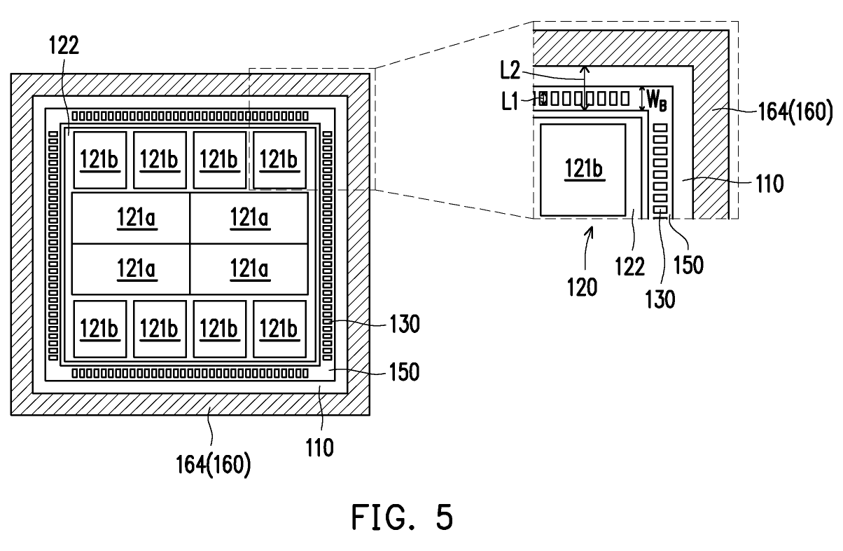

FIG. 5 is a top view schematically illustrating the relationship between a dam structure and passive components mounted on a packaging substrate in accordance with some embodiments of the present disclosure.

Referring to FIGS. 4 and 5, the semiconductor device 120 including the semiconductor dies 121a and 121b laterally encapsulated by the insulating encapsulation 122 is surrounded by the passive components 130 and the dam structure 150. The passive components 130 are arranged along a ring-shaped path (e.g., a rectangular ring-shaped path), and the dam structure 150 may covers as well as extend along the ring-shaped path such that the passive components 130 are covered by the dam structure 150. In order to cover as well as seal the passive components 130 properly, the bottom width W_{B} of the dam structure 150 may be greater than the lateral dimension L1 of the passive components 130. As illustrated in the right portion of FIG. 5, a lateral distance L2 between the semiconductor device 120 and the foot portion 164 of the lid 160 is greater than the bottom width W_{B} of the dam structure 150, and the bottom width W_{B} of the dam structure 150 is greater than the lateral dimension L1 of the passive components 130.

Since the bottom width W_{B} of the dam structure 150 is greater than the lateral dimension L1 of the passive components 130, the dam structure 150 is strong enough to prevent the bleeding of the deformed portions 129a of the thermal interface material 129 (shown in FIG. 3).

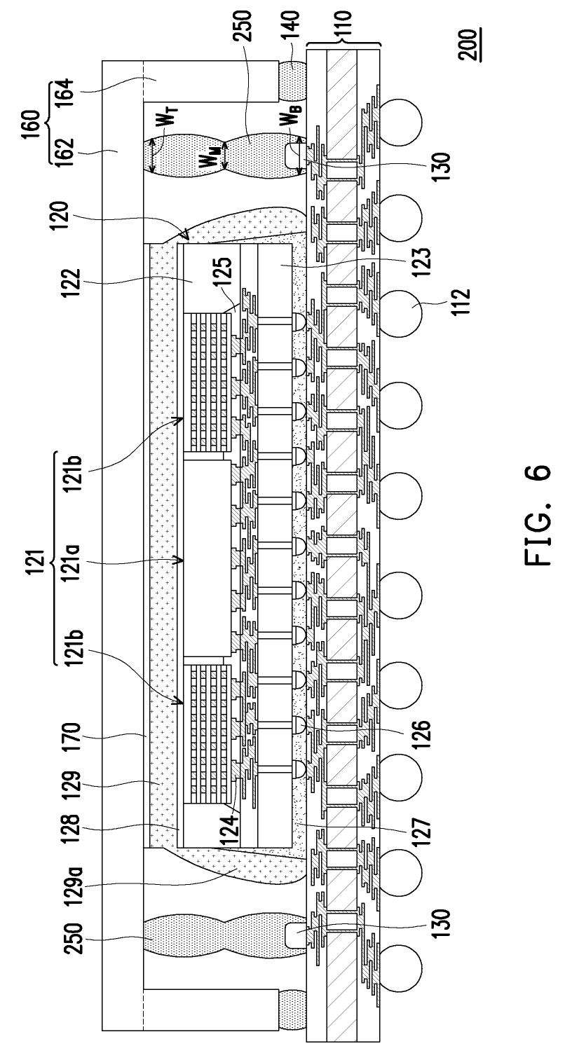

FIG. 6 is a cross-sectional view schematically illustrating a Chip-on-Wafer-on Substrate (CoWoS) structure in accordance with some alternative embodiments of the present disclosure.

Referring to FIGS. 4 and 6, the package structure 200 shown in FIG. 6 is similar to the package structure 100 shown in FIG. 4 except that the geometry of the dam structure 250. As illustrated in FIG. 6, the dam structure 250 may have a bottom width W_{B}, a middle width W_{M}, and a top width W_{T}, wherein the middle width W_{M} of the dam structure 250 is less than the bottom width W_{B} of the dam structure 250 and the top width W_{T} of the dam structure 250. Furthermore, the bottom width W_{B} of the dam structure 250 may be different from the top width W_{T} of the dam structure 250. In some embodiments, the bottom width W_{B} of the dam structure 250 is greater than the top width W_{T} of the dam structure 250. In some alternative embodiments, the bottom width W_{B} of the dam structure 250 is less than the top width W_{T} of the dam structure 250. In order to cover as well as seal the passive components 130 properly, the bottom width W_{B} of the dam structure 250 may be greater than the lateral dimension of the passive components 130.

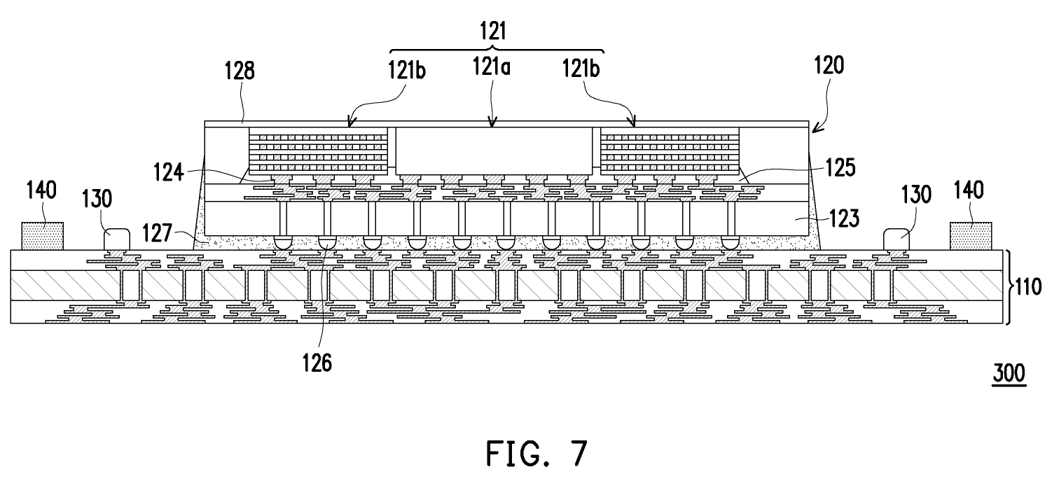

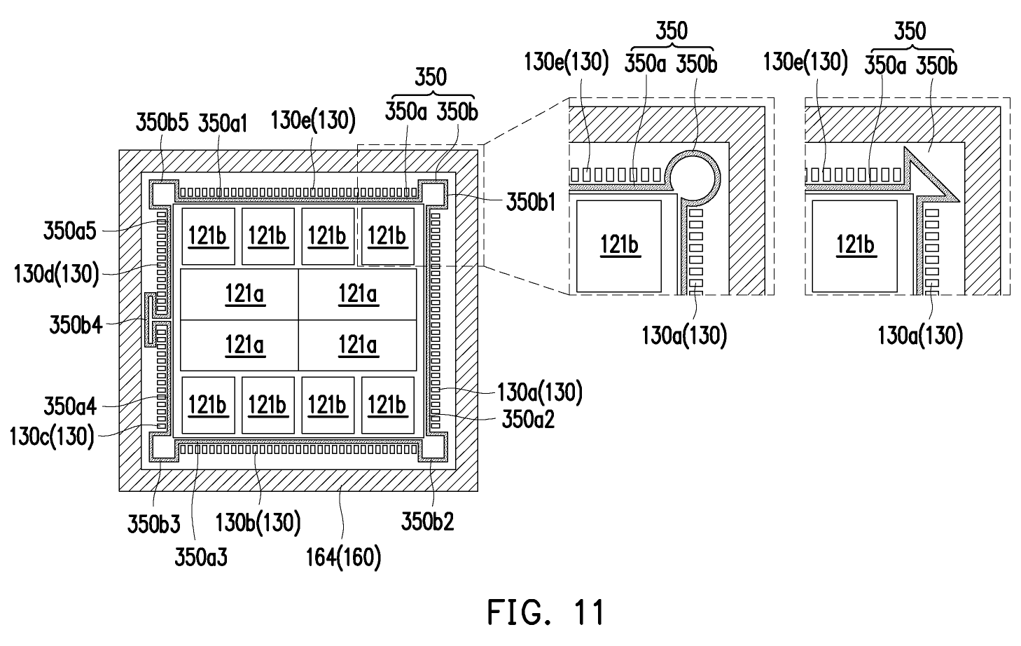

FIGS. 7-10 are cross-sectional views schematically illustrating a process flow for fabricating a Chip-on-Wafer-on Substrate (CoWoS) structure in accordance with some embodiments of the present disclosure. FIG. 11 is a top view schematically illustrating the relationship between a dam structure and passive components mounted on a packaging substrate in accordance with some alternative embodiments of the present disclosure.

Referring to FIGS. 1-4 and 7-10, the process flow illustrated in FIGS. 7-10 is similar to the process flow illustrated in FIGS. 1-4 except that the dam structure 350 in the package structure 300 is formed on the packaging substrate without covering the passive components 130.

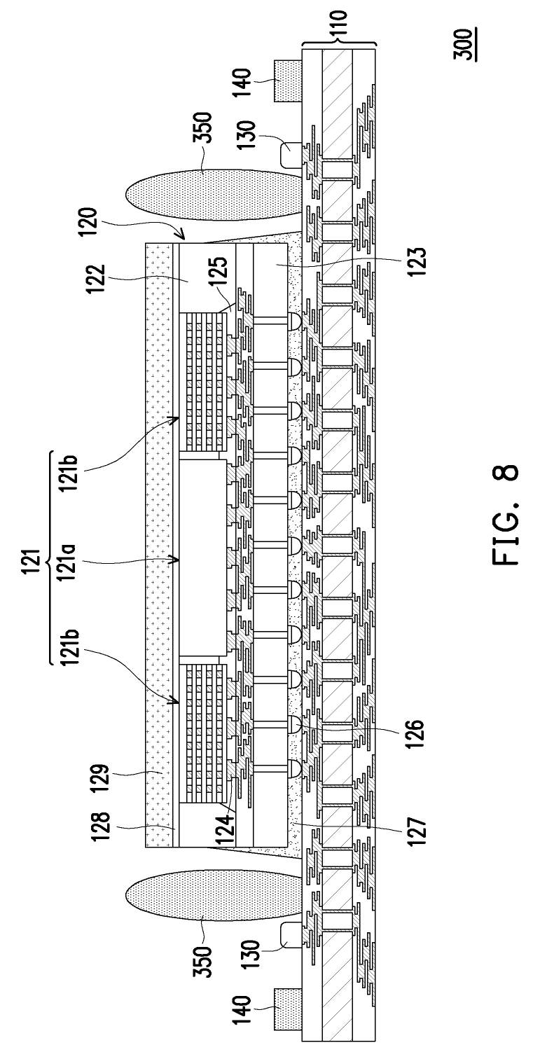

Referring to FIGS. 8 and 11, the dam structure 350 of the present embodiment includes main portions 350a and extension portions 350b. The main portions 350a extend along sidewalls of the semiconductor device 120, the extension portions 350b connect ends of the main portions 350a, and the main portions 350a and the extension portions 350b laterally enclose the semiconductor device 120. The extension portions 350b may laterally extend from ends of the main portions 350a toward the inner sidewalls of the lid 160. The main portions 350a extend between the semiconductor device 120 and the passive components 130. The first minimum distance between the main portions 350a and the inner sidewalls of the foot portion 164 of the lid 160 is greater than the second minimum distance between the extension portions 530b and the inner sidewalls of the foot portion 164 of the lid 160. In some embodiments, the passive components 130 includes multiple groups of passive components 130a, 130b 130c, 130d and 130e, and a first group 130a among the groups of passive components 130a, 130b 130c, 130d and 130e is laterally spaced apart from a second group 130b among the groups of passive components 130a, 130b 130c, 130d and 130e by one of the extension portions 350b. The passive components 130 may be distributed outside regions surrounded by the extension portions 350b of the dam structure 350. Furthermore, the regions surrounded by the extension portions 350b are distributed in proximity to corners of the semiconductor device 120 and/or midpoints of the sidewalls of the semiconductor device 120.

As illustrated in FIG. 11, the group of passive components 130a is laterally spaced apart from the group of passive components 130b by the extension portions 350b1, the group of passive components 130b is laterally spaced apart from the group of passive components 130c by the extension portions 350b2, the group of passive components 130c is laterally spaced apart from the group of passive components 130d by the extension portions 350b3, the group of passive components 130d is laterally spaced apart from the group of passive components 130e by the extension portions 350b4, and the group of passive components 130e is laterally spaced apart from the group of passive components 130a by the extension portions 350b5. The group of passive components 130a are arranged along a linear path substantially parallel to the main portion 350a2, the group of passive components 130b are arranged along a linear path substantially parallel to the main portion 350a3, the groups of passive components 130c and 130d are arranged along a linear path substantially parallel to the main portion 350a4, and the group of passive components 130e are arranged along a linear path substantially parallel to the main portion 350a1. Furthermore, the main portion 350a1 extends along a linear path between the semiconductor device 120 and the group of passive components 130e, the main portion 350a2 extends along a linear path between the semiconductor device 120 and the group of passive components 130a, the main portion 350a3 extends along a linear path between the semiconductor device 120 and the group of passive components 130b, the main portions 350a4 extends along a linear path between the semiconductor device 120 and the group of passive components 130c, and the main portions 350a5 extends along a linear path between the semiconductor device 120 and the group of passive components 130d.

The regions surrounded by the extension portions 350b1, 350b2, 350b3, and 350b5 are distributed in proximity to the corners of the semiconductor device 120. Furthermore, the region surrounded by the extension portion 350b4 is distributed in proximity to the midpoint of the sidewalls of the semiconductor device 120. In some other embodiments, the extension portions 350b1, 350b2, 350b3, 350b4 and 350b5 are of different shapes, as illustrated in right portion of FIG. 11.

Since the process details of FIGS. 7, FIGS. 9 and FIG. 10 are similar to those of FIGS. 1, FIGS. 3 and FIG. 4. The detailed descriptions regarding to FIGS. 7, FIGS. 9 and FIG. 10 are thus omitted.

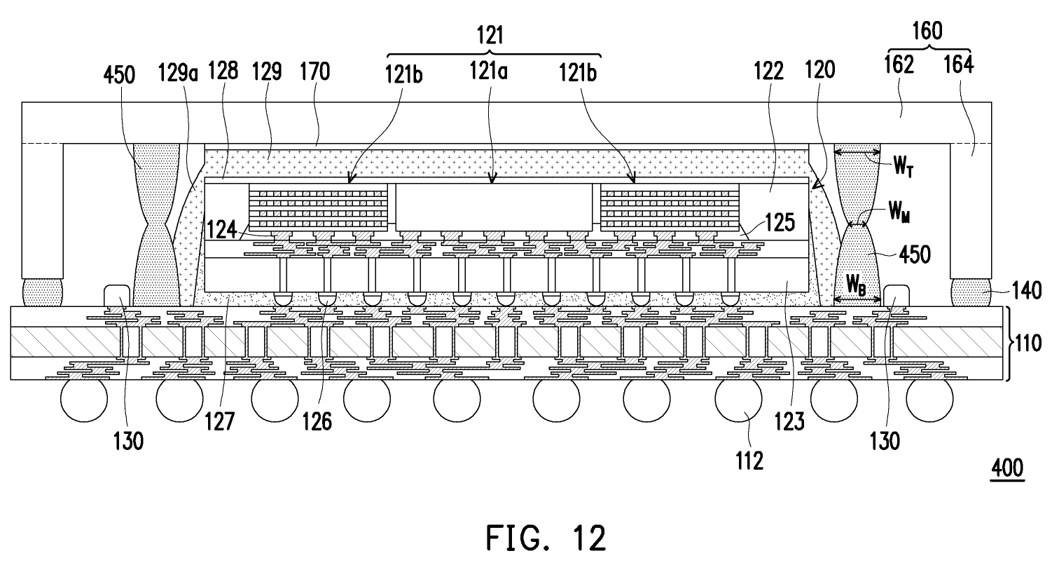

FIG. 12 is a cross-sectional view schematically illustrating a Chip-on-Wafer-on Substrate (CoWoS) structure in accordance with some other embodiments of the present disclosure.

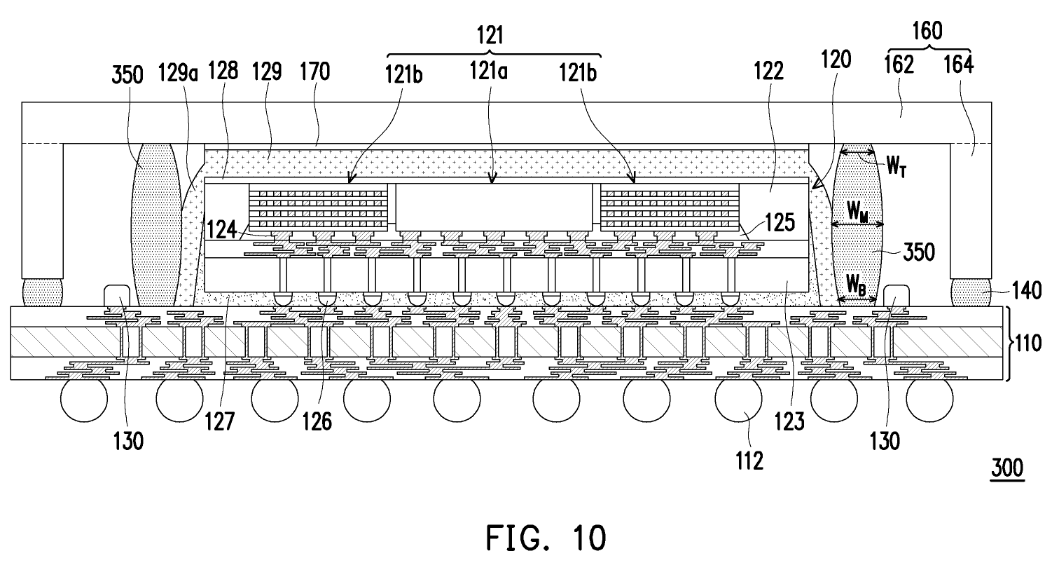

Referring to FIGS. 10 and 12, the package structure 400 shown in FIG. 12 is similar to the package structure 300 shown in FIG. 10 except that the geometry of the dam structure 350. As illustrated in FIG. 12, the dam structure 450 may have a bottom width W_{B}, a middle width W_{M}, and a top width W_{T}, wherein the middle width W_{M} of the dam structure 450 is less than the bottom width W_{B} of the dam structure 450 and the top width W_{T} of the dam structure 450. Furthermore, the bottom width W_{B} of the dam structure 450 may be different from the top width W_{T} of the dam structure 450. In some embodiments, the bottom width W_{B} of the dam structure 450 is greater than the top width W_{T} of the dam structure 450. In some alternative embodiments, the bottom width W_{B} of the dam structure 450 is less than the top width W_{T} of the dam structure 450. In order to cover as well as seal the passive components 130 properly, the bottom width W_{B} of the dam structure 450 may be greater than the lateral dimension of the passive components 130.

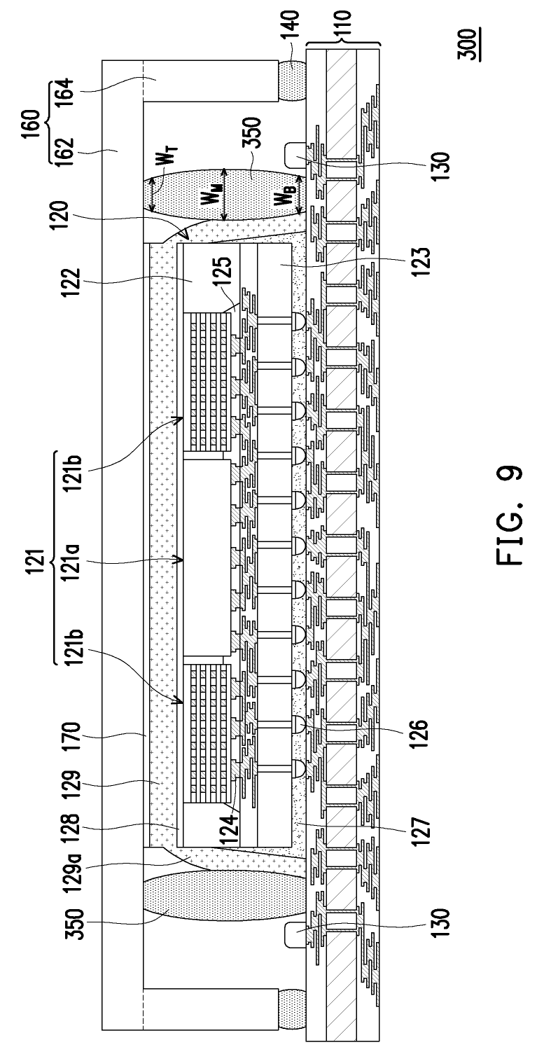

In the above-mentioned embodiment, the extension portions 350b1, 350b2, 350b3, 350b4 and 350b5 of the dam structure 350 may guide the deformed portions 129a of the thermal interface material 129 (shown in FIG. 9) such that the bleeding of the deformed portions 129a of the thermal interface material 129 can be prevented effectively. Accordingly, reliability of package structures 300 and 400 can be improved significantly.

In accordance with some embodiments of the disclosure, a package structure including a packaging substrate, a semiconductor device, passive components, a lid, and a dam structure is provided. The semiconductor device is disposed on and electrically connected to the packaging substrate. The passive components are disposed on the packaging substrate, wherein the semiconductor device is surrounded by the passive components. The lid is disposed on the packaging substrate, and the lid covers the semiconductor device and the passive components. The dam structure is disposed between the packaging substrate and the lid, wherein the dam structure covers the passive components and laterally encloses the semiconductor device. In some embodiments, the semiconductor device comprises an interposer wiring substrate, at least one semiconductor die, and an insulating encapsulant, wherein the interposer wiring substrate is disposed on and electrically connected to the packaging substrate, the at least one semiconductor die is disposed on and electrically connected to the interposer wiring substrate, and the insulating encapsulant is disposed on the interposer wiring substrate and the laterally encapsulating the at least one semiconductor die. In some embodiments, the package structure further includes a thermal interface material disposed between the semiconductor device and the lid. In some embodiments, the package structure further includes a metal layer disposed between the thermal interface material and the semiconductor device. In some embodiments, the thermal interface material comprises a metallic thermal interface material, and the metallic thermal interface material covers a top surface and sidewalls of the semiconductor device. In some embodiments, the metallic thermal interface material is in contact with the dam structure. In some embodiments, a cavity between the packaging substrate and the lid comprises an inner region between the semiconductor device and the dam structure; and an outer region between the dam structure and the lid. In some embodiments, the inner region is an air-tight region, the outer region is an open region, and the inner region is spaced apart from the outer region by the dam structure. In some embodiments, the dam structure is in contact with the passive components.

In accordance with some other embodiments of the disclosure, a package structure including a packaging substrate, a semiconductor device, a lid, and a dam structure is provided. The semiconductor device is disposed on and electrically connected to the packaging substrate. The lid disposed on the packaging substrate, and the lid covers the semiconductor device. The dam structure is disposed between the packaging substrate and the lid, wherein the dam structure comprises main portions extending along sidewalls of the semiconductor device; and extension portions connecting ends of the main portions, wherein the main portions and the extension portions laterally enclose the semiconductor device. In some embodiments, a first minimum distance between the main portions and the sidewalls of the lid is greater than a second minimum distance between the extension portions and the sidewalls of the lid. In some embodiments, the package structure further comprises passive components disposed on the packaging substrate, wherein the semiconductor device is surrounded by the passive components, and the main portions extend between the semiconductor device and the passive components. In some embodiments, the passive components comprise groups of passive components, and a first group among the groups of passive components is laterally spaced apart from a second group among the groups of passive components by one of the extension portions. In some embodiments, the passive components are distributed outside regions surrounded by the extension portions. In some embodiments, regions surrounded by the extension portions are distributed in proximity to corners of the semiconductor device and/or midpoints of the sidewalls of the semiconductor device.

In accordance with some other embodiments of the disclosure, a package structure including a packaging substrate, a semiconductor device, a lid, and a dam structure is provided. The semiconductor device is disposed on and electrically connected to the packaging substrate. The lid is disposed on the packaging substrate, and the lid covers the semiconductor device. The dam structure is disposed between the packaging substrate and the lid, wherein the dam structure comprises: main portions extending along sidewalls of the semiconductor device; and extension portions laterally extending from ends of the main portions toward inner sidewalls of the lid, and wherein the main portions and the extension portions laterally enclose the semiconductor device. In some embodiments, the package structure further includes groups of passive components disposed on the packaging substrate, wherein the semiconductor device is surrounded by the passive components, and the main portions extend between the semiconductor device and the groups of passive components. In some embodiments, a first group among the groups of passive components is laterally spaced apart from a second group among the groups of passive components by one of the extension portions. In some embodiments, regions surrounded by the extension portions are free of the groups of passive components. In some embodiments, a first minimum distance between the main portions and the sidewalls of the lid is greater than a second minimum distance between the extension portions and the sidewalls of the lid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a packaging substrate;
a semiconductor device disposed on and electrically connected to the packaging substrate;
passive components disposed on the packaging substrate, wherein the semiconductor device is surrounded by the passive components;
a lid disposed on the packaging substrate, the lid covering the semiconductor device and the passive components; and
a dam structure disposed between the packaging substrate and the lid, wherein the dam structure covers the passive components and laterally encloses the semiconductor device.

2. The package structure as claimed in claim 1, wherein the semiconductor device comprises:
an interposer wiring substrate disposed on and electrically connected to the packaging substrate;
at least one semiconductor die disposed on and electrically connected to the interposer wiring substrate; and
an insulating encapsulant disposed on the interposer wiring substrate and the laterally encapsulating the at least one semiconductor die.

3. The package structure as claimed in claim 1 further comprising a thermal interface material disposed between the semiconductor device and the lid.

4. The package structure as claimed in claim 3 further comprising a backside metal layer disposed between the thermal interface material and the semiconductor device.

5. The package structure as claimed in claim 3, wherein the thermal interface material comprises a metallic thermal interface material, and the metallic thermal interface material covers a top surface and sidewalls of the semiconductor device.

6. The package structure as claimed in claim 5, wherein the metallic thermal interface material is in contact with the dam structure.

7. The package structure as claimed in claim 1, wherein a cavity between the packaging substrate and the lid comprises:
an inner region between the semiconductor device and the dam structure; and
an outer region between the dam structure and the lid.

8. The package structure as claimed in claim 7, wherein the inner region is an air-tight region, the outer region is an open region, and the inner region is spaced apart from the outer region by the dam structure.

9. The package structure as claimed in claim 1, wherein the dam structure is in contact with the passive components.

10. A package structure, comprising:
a packaging substrate;
a lid disposed on the packaging substrate, wherein a cavity is defined between the package substrate and the lid;
a semiconductor device disposed in the cavity and electrically connected to the packaging substrate;
a passive component disposed in the cavity and electrically connected to the packaging substrate; and
a dam structure disposed in the cavity to encapsulate the passive component.

11. The package structure as claimed in claim 10, wherein the semiconductor device comprises:
an interposer wiring substrate disposed on and electrically connected to the packaging substrate;
at least one semiconductor die disposed on and electrically connected to the interposer wiring substrate; and
an insulating encapsulant disposed on the interposer wiring substrate and the laterally encapsulating the at least one semiconductor die.

12. The package structure as claimed in claim 10 further comprising a thermal interface material disposed between the semiconductor device and the lid.

13. The package structure as claimed in claim 12 further comprising a backside metal layer disposed between the thermal interface material and the semiconductor device.

14. The package structure as claimed in claim 12, wherein the thermal interface material comprises a metallic thermal interface material, and the metallic thermal interface material covers a top surface and sidewalls of the semiconductor device.

15. The package structure as claimed in claim 14, wherein the metallic thermal interface material is in contact with the dam structure.

16. The package structure as claimed in claim 10, wherein the cavity between the packaging substrate and the lid comprises:
an inner region between the semiconductor device and the dam structure; and
an outer region between the dam structure and the lid.

17. A package structure, comprising:
a packaging substrate;
a lid disposed on the packaging substrate;
a semiconductor device disposed on the packaging substrate and covered by the lid;
a passive component disposed on the packaging substrate and covered by the lid; and
a dam structure disposed on the packaging substrate, wherein the passive component is embedded in the dam structure.

18. The package structure as claimed in claim 17, wherein the dam structure extends between the packaging substrate and the lid.

19. The package structure as claimed in claim 17 further comprising:
a thermal interface material disposed between the semiconductor device and the lid.

20. The package structure as claimed in claim 19, wherein the thermal interface material is in contact with the dam structure.
